(19) United States
(12) Patent Application Publication
(10) Pub. No.: US 2010/0066356 A1
(43) Pub. Date: Mar. 18, 2010

(54) SENSOR DEVICE COMPRISING MEANS FOR DETERMINING THE SAMPLE COVERED AREA OF THE SENSITIVE SURFACE

(75) Inventors: JEROEN HANS NIEUWENHUIS, WAALRE (NL); HANS VAN ZON, WAALRE (NL); FEMKE KARINA DE THEIJE, BERGHEM (NL); JEROEN VEEN, NIJMEGEN (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/518,459

(22) PCT Filed: Dec. 11, 2007
(86) PCT No.: PCT/IB07/55024

§ 371 Date: Jun. 10, 2009

(30) Foreign Application Priority Data
Dec. 15, 2006 (EP) 06126247.3

(51) Int. Cl. G01R 33/02

(52) U.S. Cl. 324/252

(57) ABSTRACT

The invention relates to a microelectronic device (100) with means for the determination of the wetting grade of a sensitive surface (22) that lies adjacent to a sample chamber (1) with a sample fluid. In a particular embodiment, the device may be a magnetic sensor device comprising magnetic excitation wires (11, 13) for the generation of magnetic fields (B) in the sample chamber and a GMR sensor (12) for sensing reaction fields (B') generated by magnetized particles (2). A detector module (30) can optionally be adapted to measure the resistance of conductors (11, 12, 13) which depends, via the dissipation of heat generated by electrical currents, on the wetting grade of the sensitive surface (22). In another embodiment, the capacitance of conductors is measured, which is affected at the sensitive surface by the presence of gas bubbles (4).

The invention relates to a microelectronic device comprising a carrier with a sensitive surface and a sample chamber in which a sample fluid can be provided. Moreover, it relates to the use of such a device and to a method for the determination of the wetting grade of the sensitive surface in such a microelectronic device.

From the WO 2005/010543 A1 and WO 2005/010542 A2 a magnetic sensor device is known which may for example be used in a microfluidic biosensor for the detection of target molecules, e.g. biological molecules, labeled with magnetic beads. The device is provided with an array of detection units comprising wires for the generation of a magnetic excitation field and Giant Magneto Resistances (GMRs) for the detection of magnetic reaction fields generated by magnetized, immobilized beads. The signal (resistance change) of the GMRs is then indicative of the number of beads near the sensor. Due to hydrophobic properties of the sensor surface, the wetting of the sensor surface is however not always complete and air-bubbles can be present. At the location of these air-bubbles the target molecules cannot bind to the sensor surface and as a result the sensor reading becomes incorrect.

Based on this situation it was an object of the present invention to provide means that allow to take the effects of gas bubbles in microelectronic devices into account.

This object is achieved by a microelectronic device according to claim 1, a method according to claim 14, and a use according to claim 16. Preferred embodiments are disclosed in the dependent claims.

The microelectronic device according to the present invention may provide any of a large variety of functionalities depending on the specific application it is intended for. It may in particular be designed as a microfluidic device that allows the manipulation of a sample fluid, for example the execution of biochemical reactions and/or the detection of characteristic substances in such fluids. The microelectronic device comprises the following components:

a) A “carrier” that comprises a sensitive surface and at least one electrical conductor. The carrier will typically further comprise a substrate, e.g. a usual semiconductor material like silicon. The at least one electrical conductor is then embedded into said substrate or disposed on its surface by processes known to a person skilled in the art of microelectronics, and it may have any shape, dimension and structure (linear, rectangular, flat, voluminous, homogeneous, patterned, structured etc.). The term “sensitive surface” shall not restrict the design or functionality of this part of the carrier surface in any way but only provide a unique name for it, wherein this name is chosen with respect to a typical purpose of this surface, i.e. the sensing of physical properties of an adjacent sample material.
b) A “sample chamber” that is disposed adjacent to the sensitive surface and in which a sample fluid can be provided. The carrier then constitutes at least one wall of the sample chamber with the sensitive surface being the interface at which a sample fluid comes into contact with the carrier.
c) A “detector module” for sensing measurement signals from the at least one conductor that are indicative of the wetting grade of the sensitive surface in an associated measuring region. The detector module may be a circuitry that is integrated into the carrier, or it may completely or partially be external to the carrier. It will typically be connected to the at least one conductor by electrical lines, though a wireless communication between detector module and conductor is possible, too. The “wetting grade” of the considered “measuring region” reflects how much of the sensitive surface in the measuring region is actually contacted (“wetted”) by a particular sample fluid and how much of it is not contacted (“un-wetted”). The medium that contacts the un-wetted parts of the measuring region may in principle be any solid material, liquid or gas different from the sample fluid. In the following, it will be assumed for simplicity (but without loss of generality) that this medium is a gas. The wetting grade is then an indication of the extent to which gas bubbles are attached to the sensitive surface. It may in the most simple case have just two values representing the states of “wetted” and “un-wetted” (dry). In general, the wetting grade will however have a plurality of values corresponding to different degrees of the wetting or even a continuum of values that may for example represent the wetted fraction of the sensitive surface (i.e. the percentage of a considered area which is contacted by sample fluid). As a single conductor will typically not be able to indicate the wetting grade of the whole sensitive surface, the interpretation of its measurement signals has to be restricted to a measuring region associated to that conductor.

The described microelectronic device provides means for the determination of the wetting grade of the sensitive surface, which is an important parameter in many microfluidic manipulations and investigations. Moreover, said means are based on measurement signals provided by one or more conductors which are easy to implement into the substrate of a microelectronic device and which are in general already present there for other purposes. It will therefore often suffice to add a detector module for the sensing and evaluation of the measurement signals to a usual microelectronic device.

A variety of electrical signals that can be measured at a conductor are sensitive to the wetting grade of an associated surface and are therefore suited as measurement signals that indicate the wetting grade. In a first preferred embodiment of the invention, the measurement signals comprise the impedance (or, more precisely, a representation of the value of the impedance) of a circuit that comprises the at least one conductor. In the most simple case, said circuit may just comprise the conductor or, if a plurality of conductors is present, these conductors connected in series or in parallel.

The “impedance” is defined as usual as the complex, frequency dependent electrical resistance Z of a (passive) circuit between two terminals that links the voltage V and the current I applied to these terminals according to V=Z·I. The impedance typically has capacitive, inductive and (ohmic) resistive components. The value of the impedance of a circuit can readily be measured, and it is sensitive to the material surrounding the conductor, i.e. also to the wetting grade of an adjacent sensitive surface.

In a particular embodiment of the aforementioned case, the measurement signals comprise the ohmic resistance of the at least one conductor. Said ohmic resistance can simply be determined by conducting a (direct) current through the conductor and measuring the associated voltage drop according to Ohm's law. If currents can leave the conductor and flow through the nearby sensitive surface and sample chamber, the observed electrical resistance between two terminals at the ends of the conductor will obviously depend on the wetting grade of the sensitive surface. Another effect of the wetting grade on the ohmic resistance of the conductor itself (without the surroundings) is imparted by heat. Heat generated by an electrical current through the conductor will be dissipated differently depending on the wetting grade; the wetting grade will therefore determine the temperature and thus also the ohmic resistance of the electrical conductor due to its temperature coefficient.

In another particular embodiment of the invention, the measurement signals comprise the capacitance of the at least one conductor with respect to a counter electrode. Said counter electrode may be the grounded material surrounding the conductor, or preferably a second conductor of the carrier. In the latter case, the two conductors can be considered as electrodes of a capacitor, wherein the electrical field between said electrodes senses dielectric properties of the intermediate material. Arranging the sensitive surface between the electrodes of the capacitor will therefore make the capacitance dependent on the wetting grade as fluids and gases typically have largely different dielectric properties.

While the microelectronic device comprises in the most simple case just one electrical conductor, it will usually have a more or less large number (typically several hundreds) of such conductors. In a preferred embodiment, it comprises a plurality of conductors that are arranged in non-overlapping shapes at the sensitive surface. The conductors can for example be formed by a structured metal layer on the substrate of the carrier. Such metal layers, e.g. gold layers, are often present in microelectronic devices used for biological investigations as they provide a surface to which biological molecules can bind. Two neighboring conductors will in this case constitute a capacitor that senses the presence of a liquid or a gas in the volume immediately above it, i.e. in a measuring region of the sensitive surface that corresponds to the area above the conductors.

In a further development of the aforementioned embodiment, at least three conductors are arranged in shapes that meet at one point, wherein the term “meet” is to be understood as coming close together without electrically contacting. In particular, four rectangular conductors can be arranged in the quadrants of a coordinate system. Different pairs of two conductors can then be driven as one capacitor which allows to measure the wetting grade of different volumes that all comprise the volume above the meeting point.

In another embodiment of the microelectronic device with a plurality of non-overlapping conductors, at least two conductors are shaped as meshing combs. In this design, the two conductors come close to each other over a very long distance, which yields a correspondingly high capacitance and thus high sensitivity.

In a further development of the invention, the detector module comprises a “localization unit” for inferring the location of un-wetted spots on the sensitive surface from measurement signals that correspond to different measurement regions. Thus the information obtained from measurements with different conductors, which are associated to different (but typically overlapping) measurement regions on the sensitive surface, can be combined to improve the spatial solution of the measurement. If a measurement in a first measurement region indicates for example a wetting grade of 10%, this can be produced by a gas bubble of corresponding size anywhere in the first measurement region. If however a measurement in a second measurement region that partially overlaps with the first one indicates a wetting grade of 100%, than it is clear that the gas bubble cannot be in the overlapping area, which refines the spatial localization of that bubble.

The detector module may optionally comprise a driver for supplying the at least one conductor with an alternating electrical driving signal. Said driving signal may for example be a sinusoidal voltage or current having some particular frequency. Effects which are induced by said current will then usually be characterized by a corresponding frequency dependence which allows to separate them from other effects.

In another embodiment of the invention, which may particularly be realized together with the aforementioned one, the detector module comprises a “spectral processing unit” for processing the measurement signals in the frequency domain (e.g. by band-pass filtering). If the driving signal of the conductor is for example alternating as in the previous embodiment, certain physical effects produced by this signal will appear at characteristic frequencies. Processing the measurement signals in the frequency domain will therefore allow to identify and isolate these effects from other components.

The microelectronic device may further comprise a field generator for generating a magnetic and/or an electrical field in the sample chamber. Magnetic field generators are for example used in magnetic biosensors. Electrical field generators are often present in microfluidic devices for the movement of fluids and/or particles. The field generator can particularly be realized by one or more wires, wherein these wires can at the same time be used as conductors for sensing measurement signals indicative of the wetting grade.

Furthermore, the microelectronic device may comprise at least one optical, magnetic, mechanical, acoustic, thermal and/or electrical sensor element. Some of these sensor concepts are described in the WO 93/22678, which is incorporated into the present text by reference. The sensor element may preferably comprise a conductor that is simultaneously used for the determination of the wetting grade. A magnetic sensor device may be provided with excitation wires for the generation of a magnetic field and a Hall sensor or magneto-resistive elements for the detection of stray fields generated by magnetized beads. The magneto-resistive element may especially be a GMR (Giant Magneto Resistance), a TMR (Tunnel Magneto Resistance), or an AMR (Anisotropic Magneto Resistance).

The invention further relates to a method for the determination of the wetting grade of the sensitive surface of a carrier in a microelectronic device, wherein a detector module senses measurement signals from at least one conductor in the carrier and wherein the detector module infers the wetting grade in an associated measuring region from that measurement signals.

The method comprises in general form the steps that can be executed with a microelectronic device of the kind described above. Therefore, reference is made to the preceding description for more information on the details, advantages and improvements of that method.

In a preferred embodiment of the method, the at least one conductor is driven with an electrical current in order to produce the dissipation of heat. As said heat dissipation is dependent on the wetting grade of nearby surfaces, the wetting grade will determine the temperature and therefore the ohmic resistance of the conductor, which can readily be measured.

The invention further relates to the use of the microelectronic devices described above for molecular diagnostics, biological sample analysis, or chemical sample analysis, food analysis, and/or forensic analysis. In particular, the microelectronic devices described above may be used in clinical applications based on molecular diagnostics. Molecular diagnostics may for example be accomplished with the help of magnetic beads or fluorescent particles that are directly or indirectly attached to target molecules.

These and other aspects of the invention will be apparent from and elucidated with reference to the embodiment(s) described hereinafter. These embodiments will be described by way of example with the help of the accompanying drawings in which:

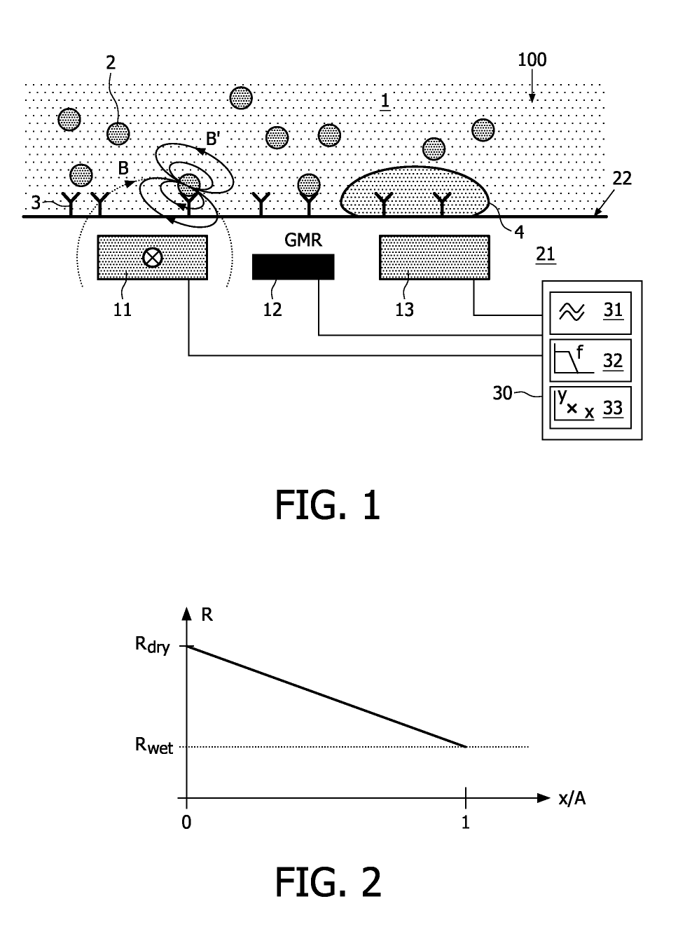

FIG. 1 shows a principal sketch of a magnetic sensor device according to the present invention with means for measuring the wetting grade of its sensitive surface;

FIG. 2 depicts a diagram showing the dependence of the ohmic resistance of a conductor on the wetted fraction of the sensitive surface for a material with a positive temperature coefficient;

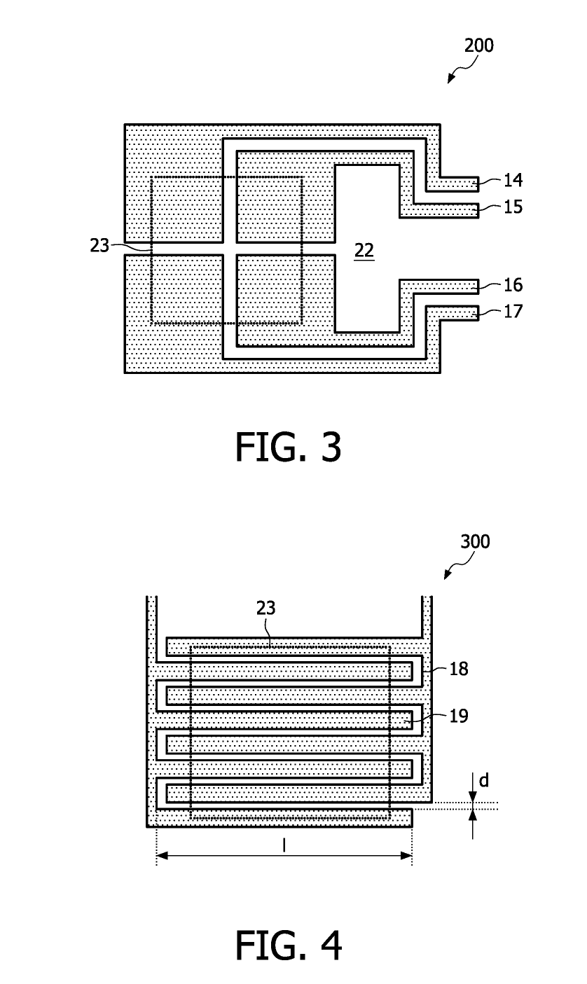

FIG. 3 shows conductors in the form of rectangular electrodes arranged in quadrants for a capacitive measurement of the wetting grade;

FIG. 4 shows two electrodes with a structure of meshing combs for capacitive measurements of the wetting grade.

Like reference numbers or numbers differing by integer multiples of 100 refer in the Figures to identical or similar components.

FIG. 1 illustrates the principle of a single sensor unit 100 for the detection of superparamagnetic beads 2. A microelectronic (bio-)sensor device consisting of an array of (e.g. 100) such sensor units 100 may be used to simultaneously measure the concentration of a large number of different target molecules (e.g. protein, DNA, amino acids, drugs of abuse) in a solution (e.g. blood or saliva) that is provided in a sample chamber 1. In one possible example of a binding scheme, the so-called “sandwich assay”, this is achieved by providing a “sensitive surface” 22 on a substrate 21 with first antibodies 3 to which the target molecules may bind. Superparamagnetic beads 2 carrying second antibodies may then attach to the bound target molecules (note that target molecules and second antibodies are not shown in the Figure for simplicity). A current flowing through the parallel excitation wires 11 and 13 that are embedded in the substrate 21 of the sensor unit 100 generates a magnetic excitation field B, which then magnetizes the superparamagnetic beads 2. The reaction field B' from the super-paramagnetic beads 2 introduces an in-plane magnetization component in the Giant Magneto Resistance (GMR) 12 of the sensor unit 100, which results in a measurable resistance change that is sensed via a sensor current. In the shown embodiment, the excitation currents and sensor currents are supplied by a driver 31 of a “detector module” 30.

The Figure further indicates that air bubbles 4 may adhere to the sensitive surface 22. As these bubbles will block the target molecules and beads 2 from binding to the associated surface area, their presence will significantly affect the measurement results. It is therefore necessary to either provide reliably a defined wetting grade of the sensitive surface 22 (preferably 100%) or to determine the wetting grade for taking it into account during the evaluation of the measurements. In the following, various embodiments of the magnetic sensor unit will be described that allow to determine the wetting grade of the sensitive surface 22. The obtained information may then (inter alia) be used in any of the two aforementioned approaches, i.e. for manipulating the sample fluid in a feedback loop until a desired, verified wetting degree is reached, or for correcting measured concentrations of magnetic particles 2 with the determined wetting grade.

In a first embodiment of the invention, a thermal detection of air-bubbles is proposed which exploits the large difference in heat-conductivity of air and water (thermal conductivity of air: 0.025 W/(mK); thermal conductivity of water: 0.6 W/(mK)). When a sensor unit 100 like that shown in FIG. 1 is activated, i.e. if currents flow through its wires, energy will be dissipated in both the GMR-sensor 12 and the excitation wires 11, 13, which results in local heating of these structures. If the sensitive surface 22 is dry, most of the heat will be transported away through the substrate 21, because of the low thermal conductivity of air. However, if the sensitive surface 22 is wetted with a watery liquid, a significant fraction of the heat is transported away through the liquid. This more efficient heat transport results in a smaller temperature increase of the dissipating element and the rest of the structures on the die. If the sensitive surface 22 is partially wetted, this will result in an intermediate temperature.

The (ohmic) resistance R of an element like the GMR-sensor 12 or the excitation wires 11, 13 can be described as:

R=R₀[1+α(T−T₀)]

where R₀ is the resistance of the element at the temperature T₀, T is the actual temperature, and α is the temperature coefficient of resistance of the element. The resistance R of the element is further additively composed of two components that correspond to the wetted and the dry surface portions, respectively, according to:

$$R = \frac{x}{A} {R}_{wet} + \frac{A - x}{A} {R}_{dry} = \frac{x}{A} {R}_{wet} + \frac{A - x}{A} {R}_{wet} [ 1 + α ( {T}_{dry} - {T}_{wet} ) ]$$

where x is the (unknown) wetted surface area, A is the “measuring region” of the element (i.e. the part of the sensitive surface 22 that can affect the considered element), R_{dry} is the resistance of the element at the temperature T_{dry} that the element reaches when it is completely dry, and R_{wet} is the resistance of the element at the temperature T_{wet} that the element reaches when it is completely wetted. The fraction x/A of wetting is thus directly proportional to the resistance R of the element. This relation, i.e. the resistance R of the element as a function of the fraction x/A of wetted surface area, is schematically depicted in FIG. 2.

According to the previous analysis, the wetted fraction x/A can be measured by monitoring the resistance R of an element through which a current is conducted. This means that it is possible to determine how well a sensor unit is wetted by electrical measurements.

The current I through the GMR sensor 12 or the excitation wires 11, 13 is typically a modulated AC-current during a normal operation of the sensor:

I=I₀ cos(ωt).

The generated power P and thus the heat dissipation is given by the product of this current I and the associated voltage V according to:

$$P = V \cdot I = {I}^{2} \cdot R = {I}_{0}^{2} \cdot {R ( cos ( ω t ) )}^{2} = \frac{1}{2} {I}_{0}^{2} \cdot R [ 1 + cos ( 2 ω t ) ]$$

So in the frequency domain one component of the impedance change due to dissipation can be found at double the modulation frequency ω. By demodulation and filtering the measured impedance in a “spectral processing unit” 32 of the detector module 30, this component can be accurately measured without interfering with the actual biosensor measurement. In a next step, the resistance value R can be determined from the measured component, which yields an indication for the wetted fraction x/A.

In another solution to detect air bubbles, it is proposed to pattern the top-layer of the sensor unit so that capacitive measurements can be performed. Since the difference in capacitance between aqueous solutions and air is very large (dielectric constant of water: 79; dielectric constant of air: 1), a capacitive measurement is a very sensitive method to detect the presence of air bubbles.

The capacitive sensor itself may be a planar sensor that is combined with a biosensor unit. The biosensor unit is typically embedded in a (silicon) substrate 21 as shown in FIG. 1. The top-layer of this chip generally consists of a gold layer to facilitate binding of biological materials. This gold layer can be patterned to implement a planar capacitive sensor, wherein a possible pattern consisting of four quadratic electrodes 14, 15, 16, and 17 arranged in quadrants above the magnetic sensor area 23 is shown in FIG. 3.

The patterning of a metal top-layer could be done such that also a position indication can be derived from the measurement. In the patterning of the top gold layer as shown in FIG. 3, capacitance can be measured between each pair of two electrodes, i.e. 14-15, 14-16, 14-17, 15-16, 15-17, and 16-17. The relative measurement results then indicate an air bubble position on the surface. If for example only the capacitances which comprise electrode 17 are low while all others are maximal, this indicates an air bubble just above electrode 17. Other detector configurations that give position information are also possible.

A still more sensitive capacitive sensor can be realized by a lateral comb structure as drawn in FIG. 4. The admittance Y (i.e. the reciprocal of the impedance) of this pattern is approximately equal to

$$Y ( ω ) = 2 N ( σ + {jωɛ}_{0} {ɛ}_{r} ) \frac{lt}{d}$$

where N equals the number of teeth of the combs, σ and εᵣ are the fluid conductivity and permittivity, respectively, l is the tooth length, d is the gap width, and t is the gold layer thickness.

Analogue to the analysis applicable to thermal detection, the admittance of the capacitive sensor is inversely proportional to the fraction x/A of wetted chip area. So by measuring the admittance at a suitable frequency, the wetted fraction can be measured.

It should be noted that for biosensor applications, the measured effect will be larger as the sensor is filled with body or buffer fluids which have a high salt concentration that increases the conductivity σ. Moreover, comb structures as shown in FIG. 4 above a magnetic sensor area 23 can also be realized at the gaps between the different quadrants of the position dependent detector shown in FIG. 3. Effectively, this increases the area of the capacitor plates, and therefore the sensitivity of the method.

In summary, means were presented to measure the surface wetting in a microelectronic device, particularly a biosensor, in the electrical domain. Monitoring the wetting of the surface area of a biosensor is essential, since incomplete wetting of the sensor would result in an erroneous reading.

One particular method is by measuring effects in the thermal domain. The main advantages of this solution are:

no external components are required;

use of signals that are already available;

the presence of air-bubbles can be detected specifically at the location of the active sensor surface.

Another particular method is by measuring the capacitance between different sensor areas. The main advantages of this solution are:

the capacitive differences between air and aqueous solutions are very large, leading to sensitive measurements;

the presence of air-bubbles can be detected specifically at the location of the active sensor surface;

the configuration can be used for other purposes besides air bubble detection, too.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A microelectronic device (100, 200, 300), comprising
a) a carrier with a sensitive surface (22) and at least one electrical conductor (11-19);
b) a sample chamber (1) that is disposed adjacent to the sensitive surface (22) and in which a sample fluid can be provided;
c) a detector module (30) for sensing measurement signals from the conductor that are indicative of the wetting grade of the sensitive surface (22) in an associated measuring region.

2. The microelectronic device (100, 200, 300) according to claim 1,
characterized in that the measurement signals comprise the impedance of a circuitry that comprises the at least one conductor (11-19).

3. The microelectronic device (100) according to claim 1,
characterized in that the measurement signals comprise the ohmic resistance (R) of the conductor (11, 12, 13).

4. The microelectronic device (200, 300) according to claim 1,
characterized in that the measurement signals comprise the capacitance of the conductor (14-19) with respect to a counter electrode.

5. The microelectronic device (200, 300) according to claim 4,
characterized in that the counter electrode is a second conductor (14-19) of the carrier.

6. The microelectronic device (200, 300) according to claim 1,
characterized in that it comprises a plurality of conductors (14-19) that are arranged in non-overlapping shapes at the sensitive surface (22).

7. The microelectronic device (200, 300) according to claim 6,
characterized in that at least three conductors (14-19) are arranged in shapes that meet at one point.

8. The microelectronic device (300) according to claim 1,
characterized in that the conductors (18, 19) are shaped as meshing combs.

9. The microelectronic device (100, 200, 300) according to claim 1,
characterized in that the detector module (30) comprises a localization unit (33) for inferring the location of un-wetted spots on the sensitive surface (22) from measurement signals that correspond to different measurement regions.

10. The microelectronic device (100, 200, 300) according to claim 1,
characterized in that the detector module (30) comprises a driver (31) for supplying the conductor (11-19) with an alternating electrical driving signal.

11. The microelectronic device (100, 200, 300) according to claim 1,
characterized in that the detector module (30) comprises a spectral processing unit (32) for processing the measurement signals in the frequency domain.

12. The microelectronic device (100, 200, 300) according to claim 1,
characterized in that it comprises a field generator (11, 13) for generating a magnetic (B) and/or an electrical field in the sample chamber (1).

13. The microelectronic device (100, 200, 300) according to claim 1,
characterized in that it comprises at least one optical, magnetic, mechanical, acoustic, thermal or electrical sensor element (12).

14. A method for the determination of the wetting grade of the sensitive surface (22) of a carrier in a microelectronic device (100, 200, 300), wherein a detector module (30)
a) senses measurement signals from at least one conductor (11-19) in the carrier, and
b) infers the wetting grade in an associated measuring region from that measurement signals.

15. The method according to claim 14,
characterized in that the conductor (11-19) is driven with an electrical current to produce heat that is dissipated to the surroundings.

16. Use of the microelectronic device according to claim 1 for molecular diagnostics, biological sample analysis, or chemical sample analysis.
